(19) United States
(12) Patent Application Publication
(10) Pub. No.: US 2006/0128171 A1
(43) Pub. Date: Jun. 15, 2006

(54) Signal processing unit for use in process automation technology to be mounted on a top-hat rail

(75) Inventors: Dieter Schmidt, Nesselwang (DE); Thomas Sandler, Schwangau (DE)

Correspondence Address: BACON & THOMAS, PLLC, 625 SLATERS LANE, FOURTH FLOOR, ALEXANDRIA, VA, 22314, US

(73) Assignee: Endress + Hauser Wetzer GmbH + Co. KG, Nesselwang (DE)

(21) Appl. No.: 10/537,342

(22) PCT Filed: Dec. 1, 2003
(86) PCT No.: PCT/EP03/13490

§ 371 Date: Dec. 12, 2005

(30) Foreign Application Priority Data
Dec. 3, 2002 (DE) 102 56 648.8

(51) Int. Cl. H05K 1/00

(52) U.S. Cl. 439/61

(57) ABSTRACT

A signal processing unit for use in process automation technology for mounting on a top-hat rail, comprising a housing for accommodating a plurality of plug-in cards, for example CPU card, I/O cards, power supply card, which can be connected with a display unit including a frame with a display, keyboard and circuit board, to form a control panel-mountable module. The signal processing unit is created by substituting an adaptation module for the display unit. The adaptation module is connected with the housing and serves for fastening to a top-hat rail. The adaptation module has a circuit board which is configured analogously to the circuit board of the display unit. Thus, the adaptation module allows for the conversion of a panel-mountable module to a top-hat rail module.

The invention relates to a signal processing unit for use in process automation technology and mountable on a top-hat rail (hereinafter “hat rail”), as defined in the preamble of claim 1.

Often used in process automation technology are recording devices, which serve for documentation, monitoring and visualization of measuring points. Newer recording devices are, as a rule, processor-controlled and frequently have a connection to control systems. The connection is accomplished mostly over a fieldbus. Examples of such field busses are Profibus®, Foundation Fieldbus®, CAN-Bus®, etc.

These recording devices include, as a rule, a housing with multiple plug-in cards, e.g. a card with a microprocessor (CPU-card), cards with analog, or digital, inputs and outputs (I/O cards) and a card for the power supply.

For visualizing the measured values, a display unit is provided, which is connected with the housing and is organized around a frame serving to receive a display, the keypad and at least one circuit board. Such recording devices are frequently installed in switchboards, e.g. control panels, and are, therefore, referred to as switchboard-installable devices. An example of such switchboard-installable devices is the product MEMOGRAPH of the firm Endress+Hauser.

Besides switchboard-installable devices, also frequently used in process automation technology are so-called hat-rail devices. Such devices are designed for especially easy mounting on a hat rail.

Frequently, it is desired to modify switchboard-installable devices for mounting on a hat rail.

Especially in the case of recording devices constructed as switchboard installable devices, mounting on a hat rail is implementable only with considerable effort. As a rule, new construction is simpler to implement than a retrofitting of existing recording devices.

Even with new construction, however, such is burdened with significant costs.

An object of the invention is, therefore, to provide a process automation signal processing unit for mounting on a hat rail, which is based on an existing recording device in the form of a switchboard-installable device and which is simple and cost-effective in implementation, without requiring expensive designing steps.

This object is achieved by a process automation signal processing unit mountable on a hat rail, as such unit is defined in claim 1.

Advantageous further developments of the invention are set-forth in the dependent claims.

The invention will now be explained in greater detail on the basis of an example of an embodiment illustrated in the drawing, the figures of which show as follows:

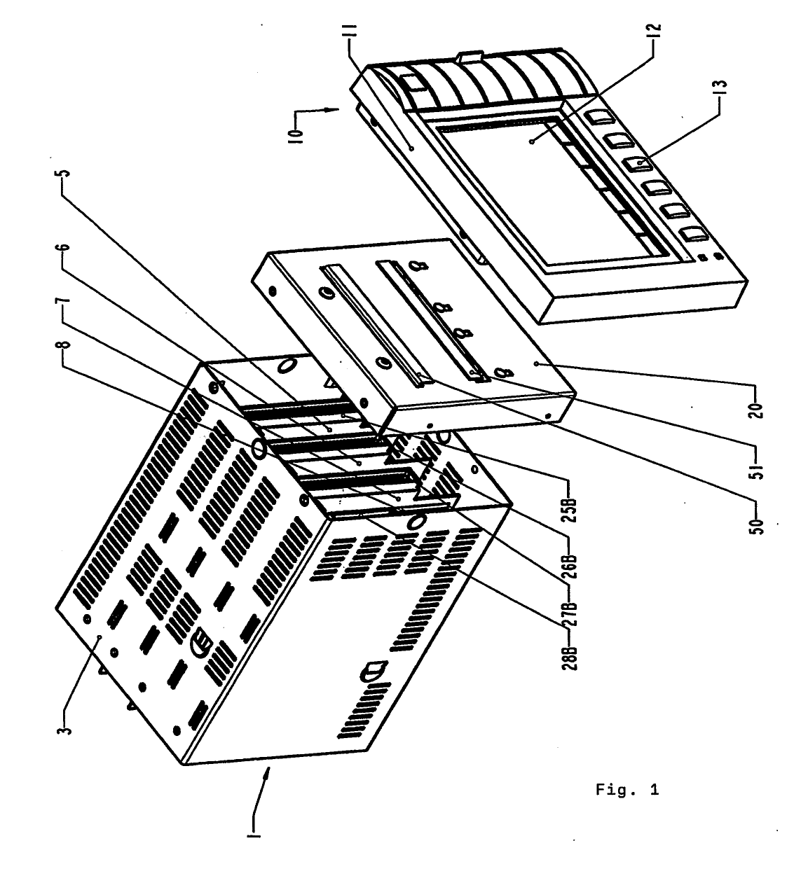

FIG. 1 perspective view of signal processing unit with adaptation module;

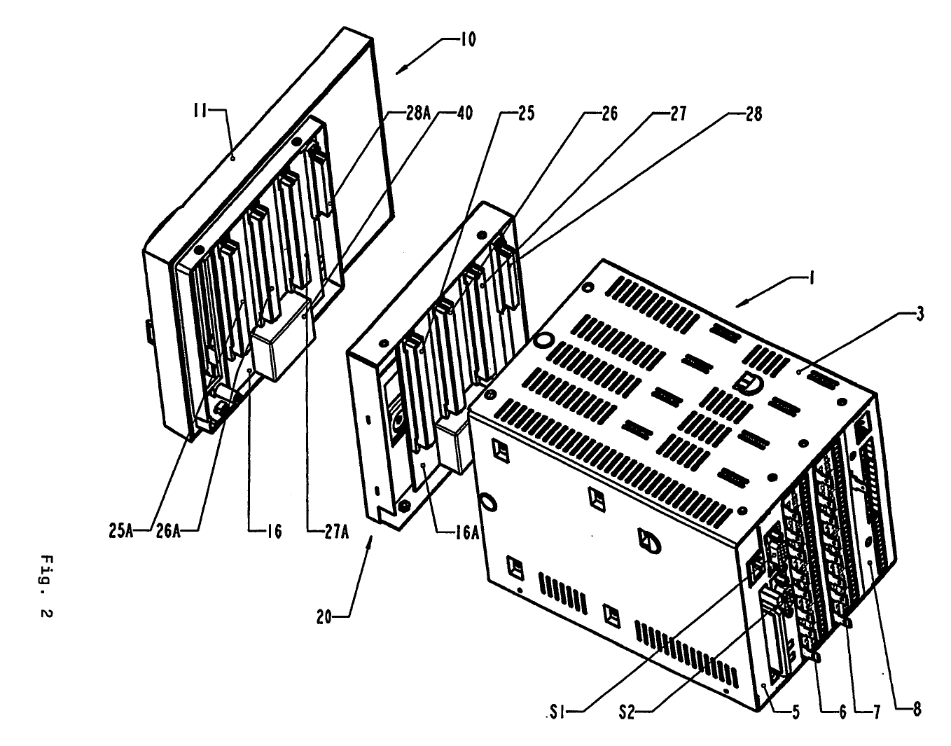

FIG. 2 perspective view from the rear of a signal processing unit according to FIG. 1;

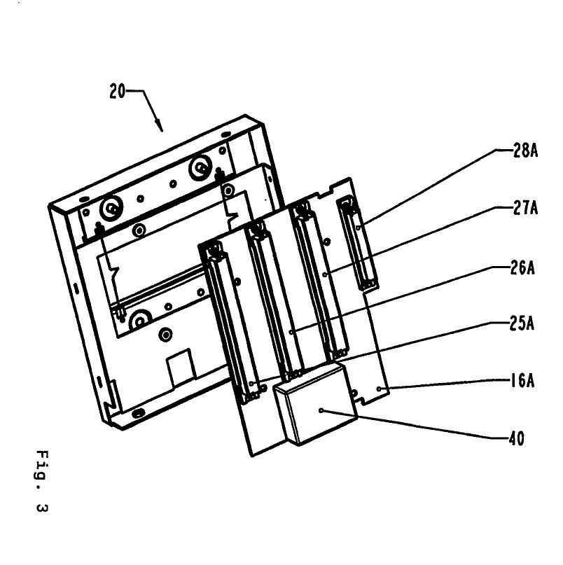

FIG. 3 perspective view of adaptation module according to FIG. 1.

FIG. 1 shows a process automation signal processing unit 1 for mounting on a hat rail, including a housing 3 serving to receive a plurality of plug-in cards 5, 6, 7, 8 (CPU card, I/O cards, power supply card). Provided on the rear side of housing 3 are two interfaces, or ports, S1 and S2 for connecting to other computer units.

Connectable with the housing 3 is an adaptation module 20, shown here in exploded view. Adaptation module 20 includes two angle sheets 50 and 51. Shown alongside the adaptation module 20 is a display unit 10, which is likewise connectable to housing 3. Connected with the display unit 10, signal processing unit 1 represents a per se known, recording device, suitable for installation in a switchboard.

The display unit 10 is composed essentially of a frame 11 with a display 12 and a keypad 13. Presentable in display 12 are e.g. plots of data. Keypad 13 enables operator input.

The display unit 10 includes a circuit board 16, which can be seen better in FIG. 2. Circuit board 16 has several card edge connectors 25A, 26A, 27A, 28A, as well as an evaluation electronics 40 for the display 12.

FIG. 3 shows a rear view of the adaptation module 20 with its circuit board 16A in exploded view.

Now the functioning of the invention will be explained in greater detail. By simple replacement of the display unit 10 by the adaptation module 20, an existing recording device for switchboard mounting can be converted into a process automation signal processing unit for mounting on a hat rail. Upon the placing of the adaptation module 20 onto the housing 3, the connection of the plug-in cards is automatically established by the card edge connectors 25, 26, 27, 28. The plug-in edges 25B, 26B, 27B, 28B on the plug-in cards 5, 6, 7, 8 are thus situated for fit both with respect to the card edge connectors 25A, 26A, 27A, 28A on circuit board 16 and with respect to the card edge connectors 25, 26, 27, 28 on circuit board 16A.

The signal processing unit 1 of the invention is especially suited for inaccessible locations of use, such as pump stations, since, in such an application, a visualization of the measured values has only limited importance for the user. As a rule, the measured values are shown on a remote computer unit, which is connected via the interfaces S1 or S2, or by modem connection, with the signal processing unit. Via such computer unit, also adjustments at the signal processing unit can be accomplished, since, in the adaptation module 20, a keypad is no longer present. Conductive traces on the circuit board 16, or 16A, as the case may be, serve for the electrical connection of the plug-in cards 5, 6, 7, 8.

Since no display is provided in the case of the adaptation module 20, the display operating electronics 40 can be omitted, this providing a cost savings in the manufacture of the adaptation module.

The resiliently mounted angle sheets 50, 51 enable a simple, snap-in connection on a hat rail.

Since the signal processing unit 1 has a significant weight, the adaptation module with the angle sheets 50, 51 is made of steel sheet, to assure a secure mounting of the unit on a hat rail.

### LIST OF REFERENCE CHARACTERS

1 signal processing unit
3 housing
5, 6, 7, 8 plug-in cards
10 display unit
11 frame
12 display
13 keypad
16, 16A circuit boards
20 adaptation module
25-28 card edge connectors
25A-28A card edge connectors
25B-28B plug-in edges
40 display operating electronics
50, 51 angle sheets
S1, S2 interfaces

1-5. (canceled)

6. A process automation signal processing unit for mounting on a hat rail, including:
a housing for receiving a plurality of plug-in cards;
a display unit;
connectable with said plurality of plug in cards, said display unit comprised of a frame with a display, a keypad and a circuit board, for forming a switchboard installable device, wherein conductive traces of said circuit board serve for the electric connection of said plurality of plug-in cards and
an adaptation module connected to said housing which serves for securement to the hat rail and which has a circuit board, whose conductive traces are laid-out correspondingly to the conductive traces of said circuit board of said display unit.

7. The process automation signal processing unit as claimed in claim 6, wherein:
on said circuit boards, card edge connectors are provided, which are situated to be mutually fitted such that, on placement of either said adaptation module or said display unit onto said housing, the connections between said plurality of plug-in cards are produced.

8. The process automation signal processing unit as claimed in claim 6, wherein:
said circuit board has display operating electronics for said display.

9. The process automation signal processing unit as claimed in claim 6, wherein:
said adaptation module has two angle sheets, of which at least one is resiliently mounted to serve for a snap-in connection with the hat rail.

10. The process automation signal processing unit as claimed in claim 6, wherein:
said adaptation module comprises steel sheet.

11. The process automation signal processing unit as claimed in claim 6, wherein:
said plurality of plug-in cards include at least one of: a CPU-card, an I/O card, and power supply card.
